(19) United States
(12) Patent Application Publication
(10) Pub. No.: US 2002/0070421 A1
(43) Pub. Date: Jun. 13, 2002

(54) Embedded gettering layer in shallow trench isolation structure

(76) Inventors: Stanton Petree Ashburn, McKinney, TX (US); Robert Howard Eklund, Plano, TX (US)

Correspondence Address: Jacqueline J. Garner, Texas Instruments Incorporated, PO Box 655474, M/S 3999, Dallas, TX, 75265, US

(21) Appl. No.: 10/071,921

(22) Filed: Feb. 8, 2002

Related U.S. Application Data
(62) Division of application No. 09/714,310, filed on Nov. 16, 2000.
Application No. 09/714,310 is a division of application No. 09/216,218, filed on Dec. 18, 1998, now abandoned.
(60) Provisional application No. 60/070,141, filed on Dec. 31, 1997.

(51) Int. Cl. H01L 21/76; H01L 29/00

(52) U.S. Cl. 257/510; 257/513; 438/424

(57) ABSTRACT

The invention includes a shallow trench isolation structure having a trench formed in the Si substrate and having an upper surface, a liner layer formed in the trench overlying the upper surface of the trench, a gettering material layer formed on the liner layer; and a filler oxide formed on the gettering material layer The gettering material layer inhibits the diffusion of metallic contaminants from the filler oxide into the surrounding silicon substrate regions

### FIELD OF THE INVENTION

This invention relates to improvements in semiconductor processing techniques, and more particularly to improved semiconductor structures and associated methods for making semiconductor structures, or the like, and still more particularly to improvements in a semiconductor structure, and associated method of making, of an embedded gettering layer in shallow trench isolation structures to isolate metallic impurities from active device regions

### BACKGROUND OF THE INVENTION

Scaled integrated circuit technologies rely on shallow trench isolation (STI) to achieve the necessary design rules with adequate isolation between active devices. Oxide is most commonly used as the isolation trench refill material The oxides are typically deposited oxides, applied using one of a variety of deposition techniques, including SACVD, LPCVD, APCVD, HDP, etc

One issue associated with these deposition techniques is that metallic impurities are commonly incorporated into the oxide during deposition due to the wafer being in physical contact with metal surfaces, evaporation of metallics, or incidental sputtering of metal from chamber surfaces. In the case of incidental sputtering, the sputtered metal can become incorporated into the sputtered film.

The metal impurities often include iron (Fe), chromium (Cr), aluminum (Al), among others, that may diffuse during subsequent thermal cycles in the process flow to interfaces in the active regions of electronic devices. The metallics diffuse relatively quickly in oxides and silicon (Si), and may getter at interfaces where active electronic devices are fabricated (i.e., gate oxide/Si interfaces, trench and SiO2 interfaces, etc.) The gettered metallics may then act as electron traps and/or generate defects that degrade device performance.

The current method for STI formation is shown in FIGS. 1a-c. A pad oxide 20 is thermally grown on a base Si 22 wafer followed by deposition of silicon nitride (Si3N4) 24 The nitride/pad oxide layers 20 and 24 are then patterned using photolithography and the nitride/pad oxide 20, 24 and Si 22 are etched to form trenches 26 in Si as indicated in Fig. 1a. The trench depth is approximately 0.2 microns to 0.7 microns as measured from the Si substrate surface.

Next a liner oxide 28 is grown in the etched trench 26, typically after a deglaze (or partial deglaze) of the pad oxide 20 under the nitride layer The deglaze exposes the Si trench 26 corner for corner-rounding purposes. The trench is then filled with oxide 30 using one of the techniques discusses above. The metallic impurities 32 are incorporated into the filler oxide 30, as discussed above. The oxide 30 is then polished back to planarize the oxide layer 30 over the Si substrate 22 This resulting structure is shown FIG. 1b

The nitride 24 is then stripped. leaving only the Si substrate 22. the trench 26, the liner oxide 28 on the Si substrate, and the filler oxide 30 This is shown in FIG. 1c The active device regions 34 are on either side of the trench structure As indicated in FIG. 1c, metallic impurities 32 are typically incorporated into the deposited filler oxide 30, and may be distributed uniformly through the oxide 30 as represented in FIG. 2. FIG. 2 is a graph of the concentration of metallic impurity vs depth after deposition of the filler oxide 30 and before any thermal cycles. Vertical line A represents the depth of the trench oxide and silicon substrate interface The trench oxide includes both the filler oxide 30 and the liner oxide 28.

The oxide 30 is then subjected to either densification thermal cycles at elevated temperatures, or to post STI module thermal cycles, either of which can lead to rapid diffusion of the impurities through the trench oxide and into the surrounding Si substrate 22. The metallic impurities may also getter at interfaces near the active device region 34, as indicated in FIG. 3 FIG. 3 shows a graph of the concentration of metallic impurity vs. depth. Vertical line A represents the interface depth of the trench oxide and the silicon substrate interface.

What is needed is a gettering layer in the STI structure of scaled integrated circuit devices to restrict the diffusion of metallic impurities from the trench filler oxide into the surrounding nearby active device region.

It is with the forgoing problems in mind that the instant invention was developed.

### SUMMARY OF THE INVENTION

The present invention concerns shallow trench isolation structure, and associated methods of making the same, and specifically an embedded gettering barrier layer in a shallow trench isolation structure, and associated method for making.

In accordance with the present invention, the inventive shallow trench isolation structure incorporates a metallic gettering layer in the trench which getters metallics away from the active device regions Examples of the material for the gettering layer are polysilicon, nitride, and implanted species, such as phosphorous.

In light of the above, therefore, the invention includes a shallow trench isolation structure having a trench formed in the Si substrate and having an upper surface, a liner layer formed in the trench overlying the upper surface of the trench, a gettering material layer formed on the liner layer, and a filler oxide formed on the Bettering material layer.

In addition, the invention includes a shallow trench isolation structure in a Si substrate of an integrated circuit, having a trench formed in the Si substrate and having an upper surface, a liner layer formed in the trench overlying the upper surface of the trench, a filler oxide formed on the liner oxide layer, and a continuous gettering material layer formed in the filler oxide layer coextensive with and spaced away from the trench upper surface and the liner layer.

Further in addition, the invention includes a shallow trench isolation structure in a Si substrate of an integrated circuit having a trench formed in the Si substrate and having an upper surface, a liner layer formed in the trench overiying the upper surface of the trench, a first gettering material layer formed on the liner layer, a filler oxide formed on the gettering material layer, and a second Bettering material layer formed in the filler oxide layer coextensive with and spaced away from the upper surface of the trench and the first gettering material layer.

It is a primary object of the present invention to provide a shallow trench isolation structure having a barrier layer to inhibit the diffusion of metallic contaminants into surrounding silicon regions.

It is an additional object of the present invention to provide a gettering material layer between the filler oxide in a shallow trench isolation structure and the surrounding silicon regions

It is an additional object of the present invention to provide a gettering material layer on top of the filler oxide after filler oxide deposition.

These and other objects. features, and advantages of the invention will become apparent to those skilled in the art from the following detailed description. when read in conjunction with the accompanying drawings and appended claims

### BRIEF DESCRIPTION OF THE DRAWINGS

FIGS. 1a-c show prior art formation of a shallow trench isolation structure.

FIG. 2 shows a representative graph of the metallic impurity distribution in the filler oxide of prior art trench structures.

FIG. 3 shows a representative graph of the metallic impurity distribution in the filler oxide of prior art trench structures after a thermal cycle(s) have been performed.

FIG. 4 shows a representative section of a shallow trench isolation structure according to the present invention, prior to subsequent thermal cycle(s).

FIGS. 5-9 show a representative section of a shallow trench isolation structure at various stages of fabrication prior to the formation of the structure shown in FIG. 4.

FIG. 10 shows a representative section of a shallow trench isolation structure according to the present invention after a thermal cycle(s).

FIG. 11 is a representative graph of the metallic impurity concentration in the shallow trench structure of the present invention after a subsequent thermal cycle(s).

FIG. 12 is a representative section of a shallow trench isolation structure according to an alternative embodiment of the present invention.

FIG. 13 is a representative graph of the metallic impurity concentration in the shallow trench structure of the alternative embodiment of the present invention after a subsequent thermal cycle

FIG. 14-16 are representative sections of a shallow trench isolation structure according to an alternative embodiment of the present invention

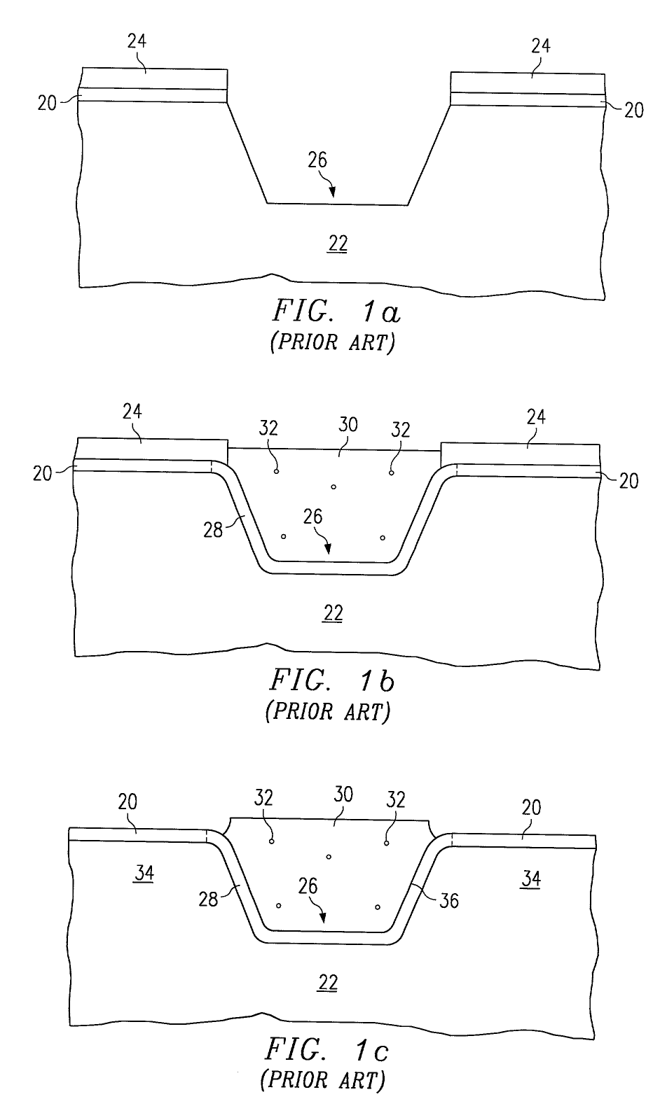

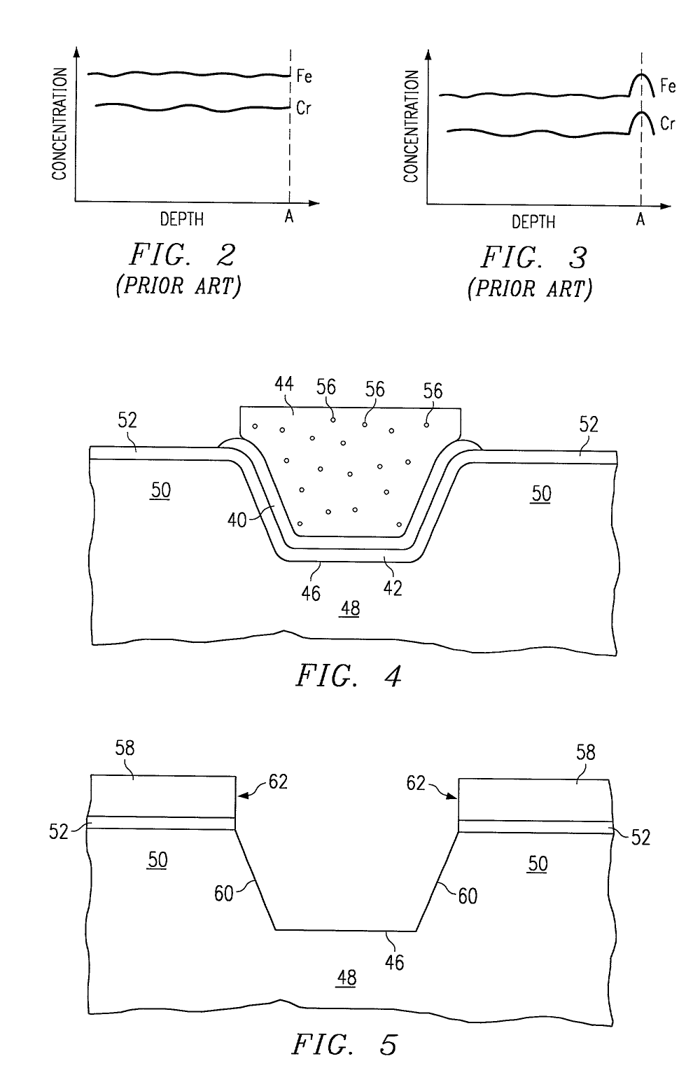

### DETAILED DESCRIPTION OF THE PREFERRED EMBODIMENT

It should be noted that the process steps and structures herein described do not necessarily form a complete process flow for manufacturing integrated circuits. It is anticipated that the present invention may be practiced in conjunction with integrated circuit fabrication techniques currently used in the art, and only so much of the commonly practiced process steps are included as are necessary for an understanding of the present invention. It will be apparent to those skilled in the art that the invention is also applicable to various integrated circuit processes, structures, and devices.

Scaled technologies (having 0.35 micron critical dimensions and below) rely on shallow trench isolation structures to achieve the necessary design rules with adequate isolation between active device regions. The instant invention incorporates a gettering layer into the trench structure to getter the metallic impurities away from the active device regions and associated interfaces

The inventive gettering layer 40 is deposited just after the liner oxidation 42 is performed, and prior to the deposition of the filler oxide 44 This results in the structure shown in FIG. 4. The gettering layer may also be positioned within the fill oxide to getter further from the liner oxide or the Si/SiO2 interface (see FIGS. 12 and 13). The barrier layer 40 may be any material that getters metallics Examples of a suitable gettering material are polysilicon, nitride, and ion-implanted species such as phosphorous.

FIG. 4 shows the structure of the shallow trench isolation after the embedded gettering layer 40 is formed therein pursuant to the instant invention. The trench 46 formed in the Si substrate 48 is to isolate laterally spaced regions, which are subsequently fabricated into active device regions 50 A layer of pad oxide 52 overlies the upper surface of the Si substrate 48 A liner oxide 42 extends from the pad oxide 52 into the trench 46 The gettering layer 40 overlies the liner oxide 42 substantially coextensive with the trench 46 Filler oxide 44 is positioned on the upper surface of the gettering layer 40 to fill the trench 46 The filler oxide 44 may extend above the top surface of the Si substrate 48 Standard integrated circuit processing techniques can then be used to complete the desired integrated circuit structure from this stage.

As discussed above, during filler oxide 44 deposition, metallic contaminants 56 can be incorporated with the filler oxide 44. These metallic contaminants 56 can include iron (Fe), chromium (Cr), aluminum (Al), among others During and after subsequent thermal cycles common to subsequent processing steps (anneals, etc.), the metallic impurities 56 are “gettered” or attracted to the Bettering layer 40, and are thus kept from diffusing from the filler oxide 44 into the adjacent active device regions 50.

The fabrication of a gettering layer 40 integral with the filler oxide 44 is discussed in greater detail with respect to FIGS. 5-9 FIG. 5 shows an isolation trench 46 formed in a Si substrate 48 The areas 50 on either side of the trench will be fabricated into active device regions in subsequent processing steps not material to the instant invention. The trench 46 is to isolate the active device regions 50 from one another. The trench 46 is defined after a layer of pad oxide 52, such as thermal SiO₂, is formed (preferably grown) in any known manner on the upper surface of the Si substrate 48. The pad oxide 52 is typically 100-200 Å thick. A layer of silicon nitride 58 (Si3N4) (hereinafter “nitride”) is then formed in any known manner on the top surface of the pad oxide 52. The nitride layer 58 is typically approximately 1000-2500 Å thick.

The pad oxide 52 and nitride 58 stack is then patterned with photoresist and etched using an anisotropic etch process to remove the exposed nitride 58, pad oxide 52, and then form the trench 46 structure as desired for the particular device The etch process can have differing etch chemistries to allow efficient etching of each different layer As shown here, preferably, the resulting trench 46 has an upper surface formed of sloped sidewalls 60 extending upwardly at an angle of approximately 80-90 degrees from horizontal After the trench 46 is formed in the etching process, sidewalls 62 of the pad oxide 52 and nitride 58 sidewalls extend substantially vertically upwardly from the edge of the top of the trench 46

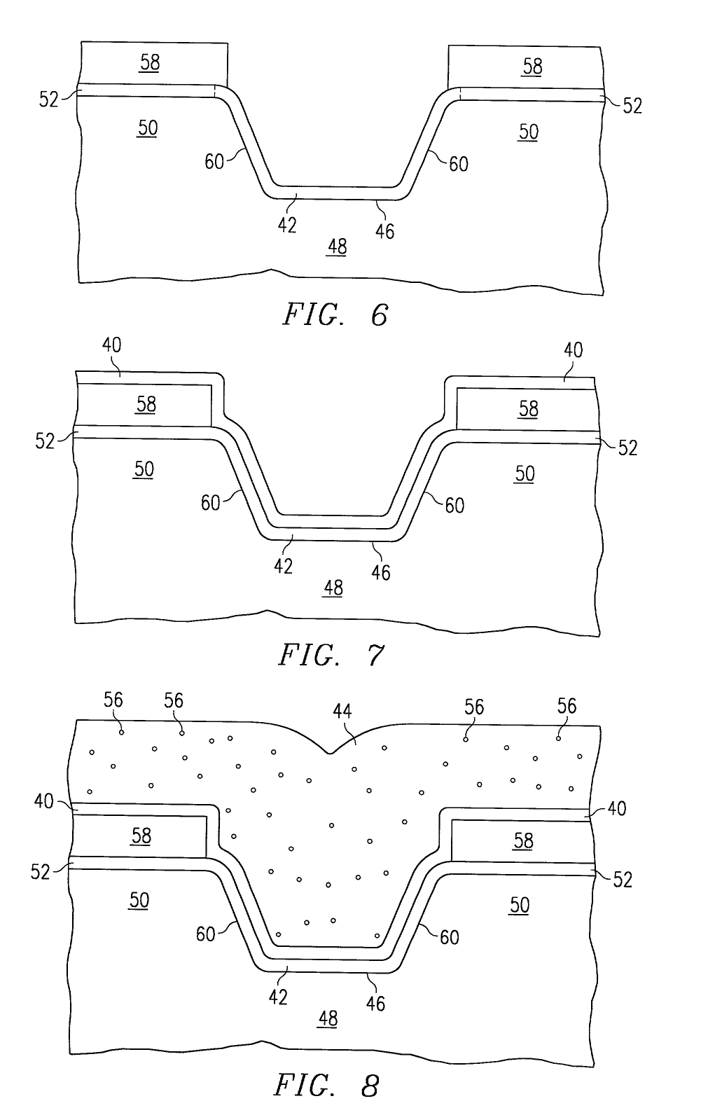

FIG. 6 shows the trench structure after a liner layer 42, such as a liner oxide of thermal SiO₂, is reformed on the trench 46 sidewalls 60 and bottom surface to a thickness of approximately 200-500 Å. Typically, the liner oxide 42 is grown in the etched trench 46 after a deglaze (or partial deglaze) of the pad oxide 52 under the edges of the nitride layer 58. The deglaze removes the pad oxide 52 under the edges of the nitride 58, and allows the liner oxide 42 to grow in those areas, which acts to round the upper corners of the trench 46, as is known in the art

FIG. 7 shows the continuous conformal formation of the inventive Bettering layer on the nitride 58 and liner oxide 42 The gettering layer 40 can be a film of polysilicon, nitride, and layers capable of ion implantation with phosphorous. or any material that acts as a gettering agent for the metallic contaminants. The gettering layer is preferably formed to a thickness of approximately 200-800 Å The gettering layer is deposited using a chemical vapor deposition process using gases such as SiH₄, SiCl₂H₂, NH₃, and H at approximately 600-700 C

Filler oxide 44, such as SiO2, is then deposited via SACVD, LPCVD, APCVD, HDP, or other suitable oxide deposition process. The filler oxide 44 completely fills the trench 46, covering the liner oxide layer 42, and also covers the exposed upper surface of the nitride layer 58, as shown in FIG. 8. As noted above, metallic contaminants 56 can be integrated into the filler oxide 44 during deposition for various reasons, such as due to the wafer being in physical contact with metal surfaces during the process, evaporation of metallics, or incidental sputtering of metal from chamber surfaces. In the case of incidental sputtering, the sputtered metal can become incorporated into the depositing oxide The metallic contaminants 56 are shown in FIG. 8 as being relatively evenly dispersed throughout the filler oxide.

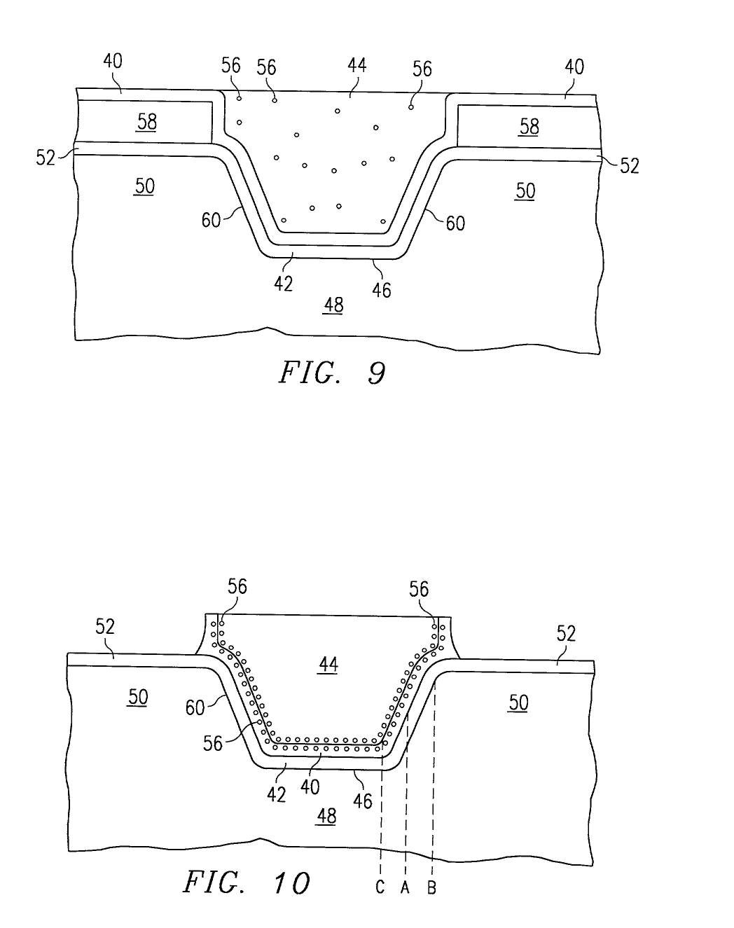

Once the filler oxide 44 has been deposited, it is planarized over the surface of the Si substrate to reduce the thickness of the filler oxide 44 over the trench 46 to the height of the nitride layer 58 surrounding the trench 46, and to expose the nitride layer 58, as shown in FIG. 9 The planarization is accomplished by mechanical polishing or anisotropic etch-back techniques, as are known in the art.

Parts of the gettering layer 40 and all of the nitride layer 58 are then removed in a known manner, such as by wet chemical etching in solutions such as hot phosphoric acid This leaves the gettering layer 40 surrounding the lower surface of the filler oxide 44 and positioned between the filler oxide 44 and the Si substrate 48, as shown in FIG. 4 As can be seen in FIG. 4, the gettering layer 40 surrounds the filler oxide.

The shallow trench structure 46 of FIG. 4 is then processed through known or standard integrated circuit fabrication techniques, not material to the instant invention, to form a functioning integrated circuit.

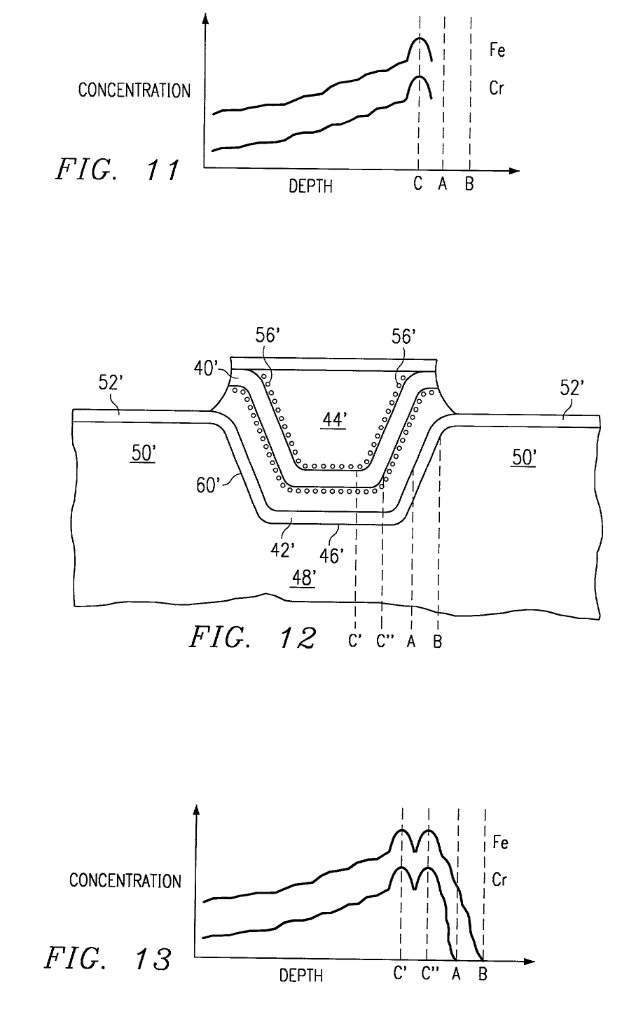

In the processing steps, having thermal cycles, subsequent to the formation of the shallow trench structure 46 of FIG. 4, the metallic contaminants 56 will migrate, or diffuse, through the filler oxide 44. They may diffuse to the layer interfaces, and into the Si substrate 48. Due to the positioning of the gettering layer 40 between the filler oxide 44 and the Si substrate 48, the metallic contaminants 56 will migrate only so far as the interface between the filler oxide 44 and the gettering layer 40, and possibly into the gettering layer 40. This is shown in FIG. 10 and represented in the graph of Fig. 11. In FIGS. 10 and 11, line A is the interface between the liner oxide layer 42 and the gettering material layer 40, line B is the interface between the liner oxide layer 42 and the Si substrate 48, and line C is the interface between the filler oxide 44 and the gettering material layer 40 The gettering layer 40 thus collects, traps, or attracts, and is a barrier to, the metallic contaminants, and keeps them from diffusing into the surrounding Si substrate 48 (which subsequently form active device regions 50) The concentration of metallics in the filler oxide are significantly reduced because the metallics are attracted toward the gettering layer

Without the gettering layer 40, the metallic contaminants 56 diffuse, due to subsequent thermal cycles, within the filler oxide 44, through the filler oxide/liner oxide interface, to the liner oxide/Si substrate interface, and on into the Si substrate 48 of the active device regions 50. These metallic contaminants may then act as electron traps and/or generate defects that degrade device performance

In an alternative embodiment, as shown in FIG. 12, the gettering layer 40′ is formed as a layer in the middle of the filler oxide 44′This structure is obtained by depositing the filler oxide 44′ in two steps, with a intermediate step for forming the gettering material layer 40′ in between. Basically, the filler oxide 44′ is partially deposited, then the gettering material layer 40′ is formed, and then the filler oxide 44′ deposition is completed. A continuous gettering material layer 40′ is thus formed in the filler oxide layer 44′ coextensive with and spaced away from the upper surface of the trench 46′, and the interface between the filler oxide 44′ and the liner oxide 42′.

The process of removing the filler oxide 44′ down to the nitride layer (not shown), to allow the nitride removal step, would require modification to allow removal of the inter-positioned gettering material layer 40′ also The metal contaminants 56′ are shown gathered at the interface between the filler oxide 44′ and the gettering material layer 40′, as would occur after a thermal cycle experienced during subsequent processing steps.

While the gettering layer 40′ is shown substantially in the middle of the thickness of the filler oxide 44′, it can be moved upwardly or downwardly within the thickness of the filler oxide 44′ as desired. The intermediate gettering layer may be formed in the filler oxide using a phosphorous implant.

FIG. 13 is a graph showing the concentration vs. depth characteristics of sample metallic contaminants 56′, i.e., iron and chromium, with respect to the various layer interfaces, after a thermal cycle during subsequent processing. Line A represents the interface between the filler oxide 44′ and the liner oxide 42′ Line B represents the interface between the liner oxide 42′ and the silicon substrate 48′Line C′ represents the innermost interface between the filler oxide 4′ and the gettering material layer 40′. Line C″ represents the outermost interface between the filler oxide 44′ and the gettering material layer 40′. As can be seen in FIG. 13, the metallic contaminants 56′ are gettered, or attracted to and held by, the gettering material layer 40′ in the filler oxide 44′, well away from the interface of the Si substrate 48′ and the liner oxide 42′.

In the above embodiments, the metallic contaminants toward the gettering layer(s) from both sides. This is partially due to the stresses created by the formation and presence of the gettering layer(s), which enhance the movement or diffusion of the metallic contaminants towards the gettering layer(s)

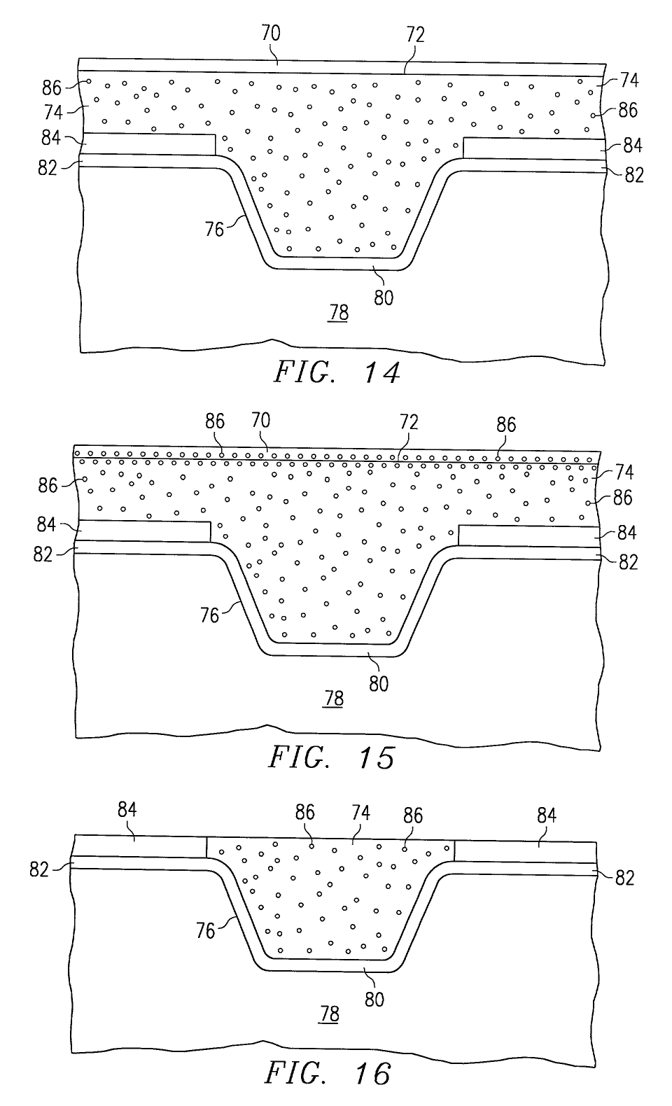

Another embodiment is shown in FIGS. 14 and 15. In this alternative embodiments the gettering layer 70 is positioned on the top surface 72 of the filler oxide 74. The other structure is as described above, with the trench 76 formed in the silicon substrate 78, and a layer of liner oxide 80 on the surface of the trench. A layer of pad oxide 82 is formed on the top surface of the silicon substrate 78 around the trench 76 A layer of nitride 84 overlies the pad oxide 82. A gettering layer 70 is deposited, as described previously, after the deposition of the filler oxide 74. After a subsequent thermal cycle, the metallics 86 diffusion to the top surface 72 of the filler oxide 74, at the interface of the filler oxide 74 with the gettering layer 70 See FIG. 15

The gettering layer 70, and the metallic contaminants 86 therein, are then removed by an etch solution (such as hot phosphoric), which removes the nitride gettering layer 70, but not the underlying filler oxide 74. The top layer of the filler oxide 74 can then be removed by a CMP (chemical mechanical polishing) step, for instance down to the nitride layer 84 Any metallic contaminants in the oxide 74 that is removed are removed also FIG. 16 shows the same structure after the CMP step

Attached as Appendices A and B, and incorporated herein in their entirety, are actual measurements taken in a shallow trench isolation structure with and without the gettering layer In Appendix A, the analysis is made in a trench isolation structure not having a gettering layer. It can be seen that the level of metallic contaminant 100 (Chromium) in the trench oxide 102 is between 10² and 10³. A pile-up of the metallic contaminant 100 is shown at the interface 104 of the trench oxide 102 and the silicon substrate 106

In Appendix B comparable measurements are made for a trench isolation structure utilizing a 500 Å gettering layer similar to that shown in FIG. 10 The metallic contaminant 108 level in the trench oxide 110 is between 10¹ and 10², showing a reduction of approximately an order of magnitude A pile up of contaminants is shown in the gettering layer 112 formed between the filler oxide 110 and the liner oxide 114

It is also contemplated that more than one gettering layer can be formed In the trench. For instance, a gettering layer can be formed on the liner oxide layer. and in the middle or on the top of the filler oxide. The planarization of the filler oxide would have to be modified accordingly to allow the removal of the underlying nitride layer.

While this invention has been described with reference to the illustrative embodiments, this description is not intended to be construed in a limiting sense. Various modifications and combinations of the illustrative embodiments, as well as other embodiments of the invention, will be apparent to persons skilled in the art upon reference to the description It is therefore intended that the appended claims encompass any such modifications or embodiments

We claim:

1. A shallow trench isolation structure in a Si substrate of an integrated circuit, said structure comprising:
a trench formed in the Si substrate and having an upper surface,
a liner layer formed in said trench overlying said upper surface of said trench;
a gettering material layer formed on said liner oxide layer; and
a filler oxide formed on said gettering material layer.

2. A shallow trench isolation structure as in claim 1, wherein said gettering material layer is made of nitride.

3. A shallow trench isolation structure as in claim 1, wherein said gettering material layer is made of polysilicon.

4. A shallow trench isolation structure as in claim 1, wherein said gettering material layer is made of a material capable of receiving an ion-implant

5. A shallow trench isolation structure as in claim 1, wherein:
said filler oxide forms sidewalls extending above the surface of the Si substrate.

6. A shallow trench isolation structure as in claim 1, wherein said gettering material layer is approximately 500 Å thick.

7. A shallow trench isolation structure as in claim 3, wherein said gettering material layer is approximately 500 Å thick.

8. A shallow trench isolation structure as in claim 2, wherein said gettering material layer is approximately 500 Å thick.

9. A shallow trench isolation structure as in claim 4, wherein said gettering material layer is approximately 500 Å thick.

10. A shallow trench isolation structure in a Si substrate of an integrated circuit, said structure comprising:
a trench formed in the Si substrate and having an upper surface;
a liner layer formed in said trench overlying said upper surface of said trench,
a filler oxide formed on said liner oxide layer; and
a continuous gettering material layer formed in said filler oxide layer coextensive with and spaced away from said trench upper surface and said liner layer.

11. A shallow trench isolation structure as in claim 10, wherein said gettering material layer is made of nitride

12. A shallow trench isolation structure as in claim 10, wherein said gettering material layer is made of polysilicon.

13. A shallow trench isolation structure as in claim 10, wherein said gettering material layer is made of a material capable of receiving an ion-implant.

14. A shallow trench isolation structure as in claim 10, wherein said filler oxide forms sidewalls extending above the surface of the Si substrate.

15. A shallow trench isolation structure as in claim 10, wherein said gettering material layer is approximately 500 Å thick.

16. A shallow trench isolation structure as in claim 12, wherein said gettering material layer is approximately 500 Å thick.

17. A shallow trench isolation structure as in claim 11, wherein said gettering material layer is approximately 500 Å thick

18. A shallow trench isolation structure as in claim 13, wherein said gettering material layer is approximately 500 Å thick

19. A shallow trench isolation structure in a Si substrate of an integrated circuit, said structure comprising
a trench formed in the Si substrate and having an upper surface,
a liner layer formed in said trench overlying said upper surface of said trench;
a first gettering material layer formed on said liner layer;
a filler oxide formed on said gettering material layer; and
a second gettering material layer formed in said filler oxide layer coextensive with and spaced away from said trench upper surface and said first gettering material layer

20. A shallow trench isolation structure as in claim 19, wherein said first and second gettering material layer is made of nitride.

21. A shallow trench isolation structure as in claim 19, wherein said first and second gettering material layer is made of polysilicon

22. A shallow trench isolation structure as in claim 19, wherein said first and second gettering material layer is made of a material capable of receiving an ion-implant.

23. A shallow trench isolation structure as in claim 19, wherein
said filler oxide forms sidewalls extending above the surface of the Si substrate.

24. A shallow trench isolation structure as in claim 19, wherein said first gettering material layer is approximately 500 Å thick.

25. A shallow trench isolation structure as in claim 21, wherein said first gettering material layer is approximately 500 Å thick

26. A shallow trench isolation structure as in claim 20, wherein said first gettering material layer is approximately 500 Å thick.

27. A shallow trench isolation structure as in claim 22, wherein said first gettering material layer is approximately 500 Å thick.

28. A shallow trench isolation structure as in claim 19, wherein a first layer of filler oxide is formed on said liner layer, and first gettering material layer is formed on said first layer of filler oxide

29. A method for forming a shallow trench isolation structure in a Si substrate of an integrated circuit, said method comprising the steps of
forming a trench in the Si substrate and having an upper surface,
forming a liner layer in said trench overlying said upper surface of said trench;
forming a gettering material layer on said liner oxide layer; and
forming a filler oxide on said Bettering material layer

30. A method for forming shallow trench isolation structure in a Si substrate of an integrated circuit, said method comprising the steps of
forming a trench in the Si substrate and having an upper surface,
forming a liner layer in said trench overlying said upper surface of said trench.
forming a filler oxide on said liner oxide layer; and
forming a continuous gettering material layer in said filler oxide layer coextensive with and spaced away from said trench upper surface and said liner layer

31. A method for forming a shallow trench isolation structure in a Si substrate of an integrated circuit, said method comprising the steps of:
forming a trench in the Si substrate and having an upper surface,
forming a liner layer in said trench overlying said upper surface of said trench,
forming a first gettering material layer on said liner layer;
forming a filler oxide on said gettering material layer; and
forming a second gettering material layer in said filler oxide layer coextensive with and spaced away from said trench upper surface and said first gettering material layer

32. A shallow trench isolation structure in a Si substrate of an integrated circuit, said structure comprising
a trench formed in the Si substrate and having an upper surface;
a liner layer formed in said trench overlying said upper surface of said trench,
a filler oxide formed on said liner layer; and
a gettering material layer formed on said filler oxide layer

33. A method for forming a shallow trench isolation structure in a Si substrate of an integrated circuit, said method comprising the steps of
forming a trench in the Si substrate and having an upper surface,
forming a liner layer in said trench overlying said upper surface of said trench;
forming a filler oxide on said liner layer, and
forming a Bettering material layer on said filler oxide layer
